(19) United States
(12) Patent Application Publication
(10) Pub. No.: US 2004/0150976 A1
(43) Pub. Date: Aug. 5, 2004

(54) Connection device

(76) Inventors: Lien-Wen Chang, Taipei (TW); Ko-Hsien Lee, Kaohsiung (TW); Chien-Ming Li, Taipei (TW)

Correspondence Address: INGRASSIA FISHER & LORENZ, P.C., 7150 E. CAMELBACK, STE. 325, SCOTTSDALE, AZ, 85251, US

(21) Appl. No.: 10/763,737

(22) Filed: Jan. 22, 2004

(30) Foreign Application Priority Data
Jan. 30, 2003 (TW) 92201897

(51) Int. Cl. H05K 7/02; H05K 7/04

(52) U.S. Cl. 361/810

(57) ABSTRACT

The present invention provides a connection device connecting a first shell of a first electronic product to a second shell of a second electronic product. The connection device includes a rivet pin having a first part and a second part, a bolt head between them, and a rivet body for engaging with the second shell. The first part of the rivet pin is provided with threads for gripping the wall of the first shell. The rivet body is provided with a slot allowing the second part of the rivet pin to pass through and engage with the rivet body to connect the second shell to the first shell.

### CROSS REFERENCE TO RELATED APPLICATIONS

This application claims priority of Taiwan Patent Application Serial No. 092201897 filed on Jan. 30, 2003.

1. Field of Invention

The present invention relates to a device for connecting two electronic products.

2. Background of the Invention

A connection device of the prior arts, including a rivet body 100 and a rivet pin 200, is shown in FIG. 1a, FIG. 1b and FIG. 2.

The rivet body 100 has in turn, a first part 101 with an arrow-alike shape, a second part 103 with a diameter, a third part 105 with a larger diameter and a forth part 107 with a still larger diameter. Between the first part 101 and the forth part 107, there is an axial slot 109. Placed between the first part 101 and the second part 103, a radial slot 111 is connected to the axial slot 109. The axial slot 109 has an end 113 with gradually increasing diameters. Conventionally, elastic materials are better for the rivet body 100 in deforming and in shock absorbing.

The rivet pin 200 is a solid rod-shaped object, having in turn, a pinpoint 202, a rod 204, and an end 206. In mounting, the end 206 of the pin is corresponding to the end 113 of the rivet body. In addition, there are bars 208, with larger diameters, placed on both ends of the rod 204. In mounting too, the diameters of the bars 208 are suitable for the axial slot 109. Moreover, the length of the rivet pin 200 is not greater than the length of the end part 113 plus the axial slot 119. Conventionally, hard materials of the rivet pin 200 are better for mounting.

The connection device of the prior arts has the rivet body 100 placed into the holes on both shells of the two objects to be connected. As illustrated in FIG. 2, the object 1 is fixed between the first part 101 and the third part 105, and the object 2 is fixed between the third part 105 and the forth part 107. Then the rivet pin 200 is stuck into the axial slot 109. Therefore, a new connection device is expected for a better usability.

### SUMMARY OF THE INVENTION

A connection device, for connecting the first shell of a first electronic product to a second shell of a second electronic product, is provided. The first shell includes a first hole defining a wall, and the second shell includes at least a second hole.

Features of the connection device lie in a rivet pin and a rivet body. The rivet pin has a first part and a second part. The first part with threads thereon engages with the wall of the first shell enabling the rivet pin to mount onto the first shell. A bolt head, located between the first part and second part of the rivet pin, is provided for users to rotate the rivet pin. Inserted into the second hole to connect to the second shell, the rivet body has an axial slot allowing that the second part of the rivet pin passes through and engages with the rivet body to connect the first shell and the second shell.

Moreover, a rivet device is provided for connecting a fan to the first shell of a first electronic product. The first shell includes a first hole defining a wall, and the fan has a second shell including at least a second hole.

The rivet device includes a rivet pin and a rivet body. The rivet pin has a first part and a second part. The first part with threads thereon enables the rivet pin to mount onto the first shell. A bolt head, located between the first part and second part of the rivet pin, is provided for users to rotate the rivet pin. Inserted into the second hole to connect to the second shell, the rivet body has an axial slot allowing that the second part of the rivet pin passes through and engages with the rivet body to connect the first shell and the second shell.

### BRIEF DESCRIPTION OF THE DRAWINGS

FIG. 1a and 1b are respectively schematic diagrams of a rivet body and of a rivet pin according to the prior arts.

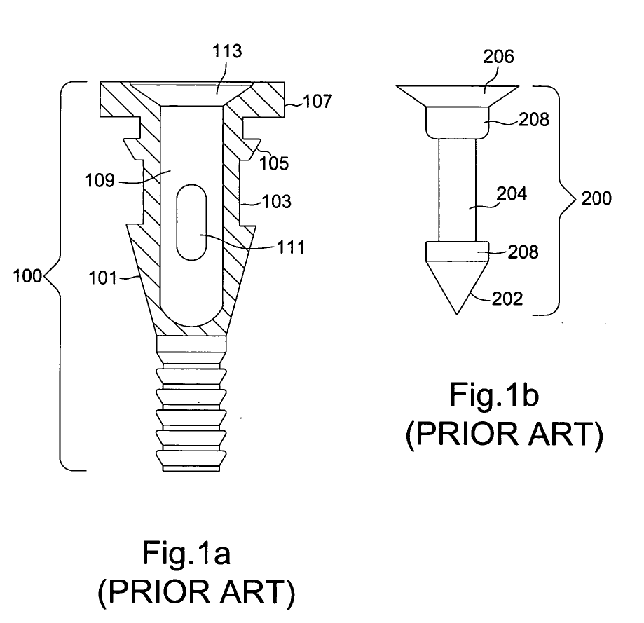

FIG. 2 is a schematic diagram of a connection device according to the prior arts;

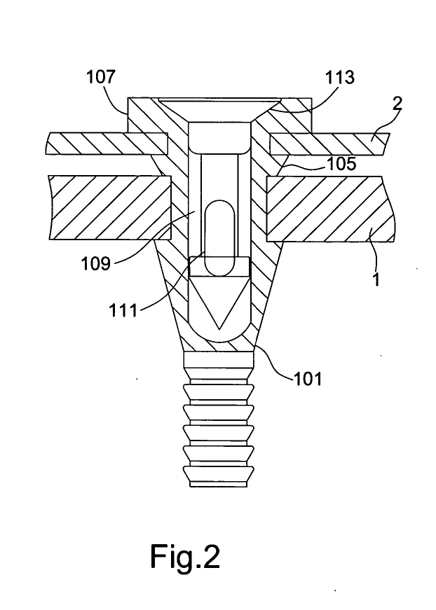

FIG. 3 is a schematic diagram of a rivet pin according to an embodiment of the present invention; and

FIG. 4 is a schematic diagram of a connection device according to an embodiment of the present invention.

### DETAILED DESCRIPTION

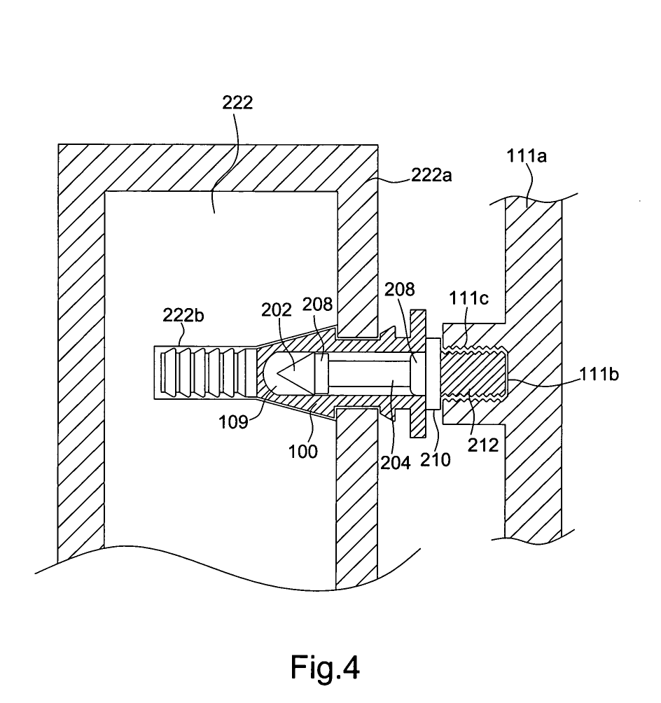

A connection device, as shown in FIG. 4, for connecting a first shell 11a of a first electronic product to a second shell 222a of a second electronic product, is provided. The first shell 111a includes a first hole 111b defining a wall 111c, and the second shell 222a includes at least a second hole 222b.

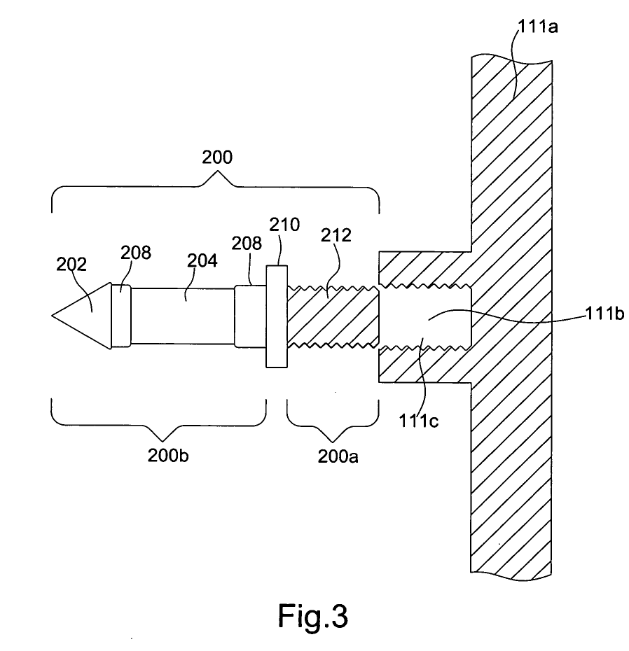

Features of the connection device lie in a rivet pin 200 and a rivet body 100, as illustrated in FIG. 3. The rivet pin 200 has a first part 200a, a second part 200b, and/or a bolt head 210. The first part 200a with threads 212 thereon engages with the wall 111c of the first shell 111a enabling the rivet pin 200 to mount onto the first shell 111a. As for the second part 200b, there are, in turn, a pinpoint 202, then a rod 204 with a diameter, and bars 208 placed on both ends of the rod 204. A bolt head 210, located between the first part 200a and the second part 200b of the rivet pin, is provided for users to rotate the rivet pin 200. Inserted into the second hole 222b to connect to the second shell 222a, the rivet body 100 has an axial slot 109 allowing that the second part 200b of the rivet pin 200 passes through and engages with the rivet body 100 to connect the first shell 111a and the second shell 222a. In mounting, the diameters of the bars 208 are corresponding to the axial slot 109, and the length of the second part 200b is not greater than the total length of the axial slot 109.

With the device described above, the connecting positions of both the first shell 111a and the second shell 222a can be decided with better precision and fewer limitations. In addition to an improved usability, the connection device has less weight.

Another object of this invention is to provide a rivet device, as shown in FIG. 3 and FIG. 4, for connecting a fan 222 to the first shell 111a of an electronic product, is provided. The fan 222 has a second shell 222a. The first shell 111a includes a first hole 111b defining a wall 111c, and the second shell 222a includes at least a second hole 222b. The fan and the alike serve as coolers in electronic products, such as projectors.

The rivet device has a rivet pin 200 including a first part 200a, a second part 200b, and a bolt head 210. The first part 200a with threads 212 thereon engages with the wall 111c of the first shell 111a enabling the rivet pin 200 to mount onto the first shell 111a. As for the second part 200b, there are, in turn, the pinpoint 202, the rod 204 with a diameter, and bars 208 placed on both ends of the rod 204. A bolt head 210, located between the first part 200a and the second part 200b of the rivet pin, is provided for users to rotate the rivet pin 200. The rivet device further has a rivet body 100. Inserted into the second hole 222b to connect to the second shell 222a, the rivet body 100 has an axial slot 109 allowing that the second part 200b of the rivet pin 200 passes through and engages with the rivet body 100 to connect the first shell 111a and the second shell 222a. In mounting, the diameters of the bars 208 are corresponding to the axial slot 109, and the length of the second part 200b is not greater than the total length of the axial slot 109.

While this invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

1. A connection device for connecting a first shell of a first electronic product to a second shell of a second electronic product, said first shell having a first hole defining a wall, said connection device comprising:
a rivet pin, said rivet pin having a first part and a second part, said first part being provided with threads engaging with said wall for fixing said rivet pin on said first shell, and said second part attaching said second shell for connecting said second shell to said first shell.

2. The connection device of claim 1, wherein said second shell has at least a second hole.

3. The connection device of claim 2, wherein said connection device further comprises a rivet body being inserted into said second hole for connecting to said second shell, and said rivet body being provided with a slot allowing said second part to pass through, and said second part engaging with said rivet body for connecting said second shell to said first shell.

4. The connection device of claim 1, wherein said rivet pin further comprises a bolt head located between said first part and said second part allowing users to rotate said rivet pin.

5. A rivet device for connecting a fan to a first shell of a first electronic product, said first shell having a first hole defining a wall, said fan having a second shell having at least a second hole, said rivet device comprising:
a rivet pin, said rivet pin having a first part and a second part, said first part being provided with threads engaging with said wall for fixing said rivet pin on said first shell; and
a rivet body being inserted into said second hole for connecting to said second shell, and said rivet body being provided with a slot allowing said second part to pass through and to engage with said rivet body.

6. The rivet device of claim 5, wherein said rivet pin further comprises a bolt head located between said first part and said second part allowing users to rotate said rivet pin.
